(19) United States
(12) Patent Application Publication
(10) Pub. No.: US 2008/0013389 A1
(43) Pub. Date: Jan. 17, 2008

(54) Random access memory including test circuit

(76) Inventors: Jaehee Kim, South Burlington, VT (US); David Hope, Jericho, VT (US); Barry Hulce, South Burlington, VT (US); Chae-Hyoun Park, Essex Junction, VT (US)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/484,255

(22) Filed: Jul. 11, 2006

(51) Int. Cl. G11C 29/00; G11C 7/00

(52) U.S. Cl. 365/201

(57) ABSTRACT

A random access memory including input pads and a test circuit. The input pads are configured to receive a row address and a column address. The test circuit is configured to receive the row address and the column address via the input pads and to receive mask bits. The test circuit selects bits of the row address and the column address based on the mask bits and provides at least one test data bit based on the selected bits of the row address and the column address.

### BACKGROUND

Typically, a computer system includes a number of integrated circuits that communicate with one another to perform system applications. Often, the computer system includes a controller, such as a micro-processor, and one or more memory components, such as a random access memory (RAM). The RAM can be any suitable type of RAM, such as dynamic RAM (DRAM), double data rate synchronous DRAM (DDR-SDRAM), graphics DDR-SDRAM (GDDR-SDRAM), reduced latency DRAM (RLDRAM), pseudo static RAM (PSRAM), and low power DDR-SDRAM (LPDDR-SDRAM).

Integrated circuits are tested after fabrication to ensure that the components operate properly. The integrated circuits are usually tested in wafer form and after being diced and packaged. Integrated circuit testers have a limited number of resources available for testing components. Resource limitations include the number of driver circuits that send inputs to one or more components under test and the number of driver/comparator circuits that judge the outputs from the components under test. If fewer resources are needed to test each component, more components can be tested in parallel, which decreases the per-unit cost of each tested component.

Memory testers often use a group of driver pins and one or more driver/comparators to test a memory component. Typically, the driver pins drive two or more memory components in parallel and separate driver/comparators judge the outputs from each memory component. Often, the number of memory components tested in parallel is limited by the number of outputs from each memory component and the number of available driver/comparator pins.

A typical memory test includes writing data to memory cells and reading the data back from the memory cells. The data read from the memory cells is compared to the data written into the memory cells. Comparison results are compressed into a limited number of outputs, which are provided from the memory component to the driver/comparators via output pads. If the data read from the memory cells matches the data written to the memory cells, the memory component passes. If the data read from the memory cells does not match the data written to the memory cells, the memory component includes defective memory cells.

Some memory components include an internal data pattern generator that generates test data patterns for testing memory cells in test mode. The test data patterns are written into memory cells and read back from the memory cells to obtain the comparison results. Often, the internal data pattern generator provides a limited number of predetermined test data patterns. This leads to testing that lacks flexibility and degrades debugging and failure analysis efforts.

For these and other reasons there is a need for the present invention.

### SUMMARY

One aspect of the present invention provides a random access memory including input pads and a test circuit. The input pads are configured to receive a row address and a column address. The test circuit is configured to receive the row address and the column address via the input pads and to receive mask bits. The test circuit selects bits of the row address and the column address based on the mask bits and provides at least one test data bit based on the selected bits of the row address and the column address.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 is a diagram illustrating one embodiment of a test system.

FIG. 2 is a diagram illustrating one embodiment of a test circuit that includes an address controlled data pattern generator and a compare circuit.

FIG. 3 is a diagram illustrating one embodiment of an address controlled data pattern generator.

FIG. 4 is a diagram illustrating one embodiment of a data pattern generator.

FIG. 5 is a diagram illustrating one embodiment of a compare circuit.

FIG. 6 is a diagram illustrating one embodiment of a control circuit.

FIG. 7A is a truth table illustrating the operation of an address controlled data pattern generator that selects the least significant bit of a row address and the least significant bit of a column address.

FIG. 7B is a truth table illustrating the operation of an address controlled data pattern generator that selects the least significant bit of a column address.

FIG. 7C is a truth table illustrating the operation of an address controlled data pattern generator that selects the least significant bit of a row address.

FIG. 7D is a truth table illustrating the operation of an address controlled data pattern generator that masks off the row address bits and the column address bits.

FIG. 7E is a truth table illustrating the operation of an address controlled data pattern generator that selects the two least significant bits of a row address.

FIG. 7F is a truth table illustrating the operation of an address controlled data pattern generator that selects the two least significant bits of a column address.

FIG. 7G is a truth table illustrating the operation of an address controlled data pattern generator that selects the second bits of a row address and a column address.

FIG. 7H is a truth table illustrating the operation of an address controlled data pattern generator that selects the two least significant bits of the row address and the two least significant bits of the column address.

FIG. 7I is a truth table illustrating the operation of an address controlled data pattern generator that selects the least significant bit of a row address and the least significant bit of a column address and receives a hexadecimal A in row write data.

FIG. 7J is a truth table illustrating the operation of an address controlled data pattern generator that selects the least significant bit of a row address and receives a hexadecimal A in row write data.

FIG. 7K is a truth table illustrating the operation of an address controlled data pattern generator that masks off row address bits and column address bits and receives a hexadecimal A in row write data.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

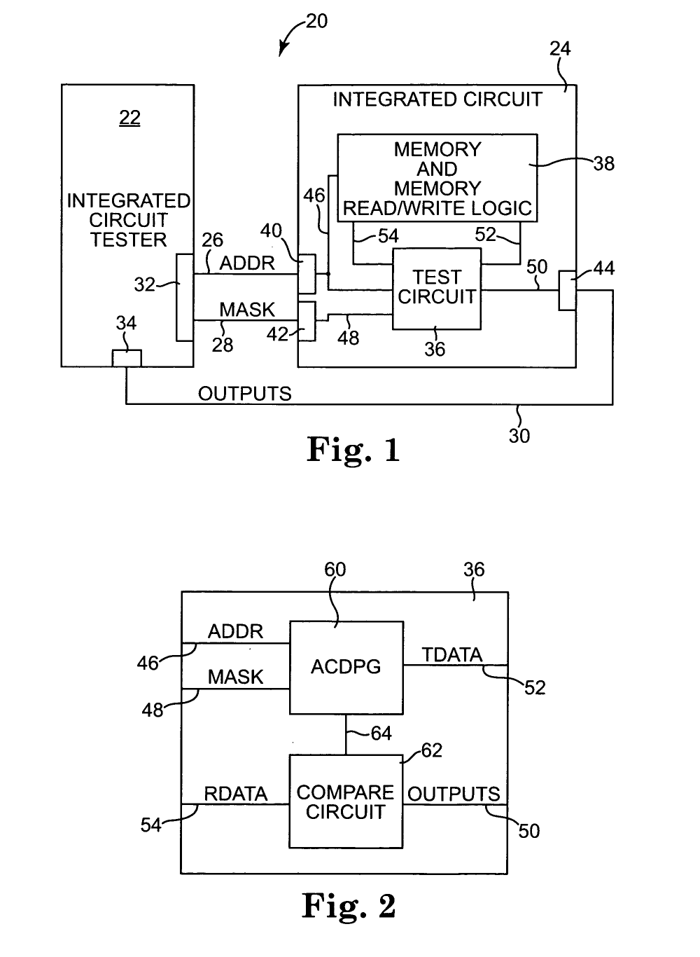

FIG. 1 is a diagram illustrating one embodiment of a test system 20 that includes an integrated circuit tester 22 and an integrated circuit 24 according to the present invention. Integrated circuit tester 22 is electrically coupled to integrated circuit 24 via address signal paths 26, mask signal path 28, and output signal paths 30. Integrated circuit tester 22 provides signals to and receives signals from integrated circuit 24 to test integrated circuit 24. Integrated circuit tester 22 can be electrically coupled to any suitable number of integrated circuits, such as integrated circuit 24, to test the integrated circuits in parallel. In one embodiment, integrated circuit tester 22 is electrically coupled to multiple integrated circuits in parallel via address signal paths 26 and mask signal path 28. In one embodiment, integrated circuit tester 22 is electrically coupled to each of multiple integrated circuits via separate output signal paths, such as output signal paths 30 that are electrically coupled to integrated circuit 24.

Integrated circuit tester 22 includes drivers 32 that provide address signals ADDR on address signal paths 26 and mask signals MASK on mask signal path 28. Address signals ADDR at 26 include row addresses and column addresses that can be used to address on-board memory in integrated circuit 24. In a test mode of operation, integrated circuit 24 receives the address signals ADDR at 26 and the mask signals MASK at 28 from integrated circuit tester 22 and generates test data based on the received address signals ADDR at 26 and mask signals MASK at 28. Integrated circuit 24 writes the test data into the on-board memory and later reads the memory and compares the test data to the data read from the on-board memory. Pass/fail comparison results are compressed and output in the compressed pass/fail output signals OUTPUTS to integrated circuit tester 22 via output signal paths 30. Integrated circuit tester 22 includes driver/comparators 34 that receive the compressed pass/fail output signals OUTPUTS at 30 from integrated circuit 24.

Integrated circuit 24 includes a test circuit 36, memory and memory read/write logic 38, address signal input pads 40, mask signal input pad 42, and output signal pads 44. Integrated circuit 24 can be any suitable type of integrated circuit that includes memory elements or memory cells. In one embodiment, integrated circuit 24 is a controller. In other embodiments, integrated circuit 24 is a RAM, such as a DRAM, DDR-SDRAM, GDDR-SDRAM, RLDRAM, PSRAM, or a LPDDR-SDRAM.

Address signal input pads 40 are electrically coupled to integrated circuit tester 22 via address signal paths 26 and mask signal input pad 42 is electrically coupled to integrated circuit tester 22 via mask signal path 28. Address signal input pads 40 receive address signals ADDR at 26 and mask signal input pad 42 receives mask signals MASK at 28. Also, output signal pads 44 are electrically coupled to integrated circuit tester 22 via output signal paths 30 and compressed pass/fail output signals OUTPUTS at 30 are provided to integrated circuit tester 22 via output signal pads 44.

Test circuit 36 is electrically coupled to address signal input pads 40 via internal address signal paths 46 and to mask signal input pad 42 via internal mask signal path 48. Also, test circuit 36 is electrically coupled to output signal pads 44 via internal output signal paths 50. Test circuit 36 receives address signals ADDR at 26 via address signal input pads 40 and internal address signal paths 46. Test circuit 36 receives mask signals MASK at 28 via mask signal input pad 42 and internal mask signal path 48. Test circuit 36 provides compressed pass/fail output signals OUTPUTS at 30 via internal output signal paths 50 to output signal pads 44 and integrated circuit tester 22.

Memory and memory read/write logic 38 is electrically coupled to address signal input pads 40 via internal address signal paths 46. In a normal mode of operation, memory and memory read/write logic 38 receive address signals ADDR at 26 via address signal input pads 40 and internal address signal paths 46.

In a test mode of operation, test circuit 36 receives the address signals ADDR at 26 and the mask signals MASK at 28 from integrated circuit tester 22 and generates test data based on the received address signals ADDR at 26 and mask signals MASK at 28. Test circuit 36 is electrically coupled to memory and memory read/write logic 38 via write data paths 52 and read data paths 54. Test circuit 36 selects bits of the row address and the column address in address signals ADDR at 26 based on mask bits in the mask signals MASK at 28. Test circuit 36 provides test data based on the selected bits of the row address and the column address to memory and memory read/write logic 38 via write data paths 52. Write logic in memory and memory read/write logic 38 writes the test data into the memory in memory and memory read/write logic 38. Test circuit 36 later reads the memory via read logic in memory and memory read/write logic 38 and receives the read data via read data paths 54. Test circuit 36 compares the test data to the data read from the memory and provides pass/fail comparison results. The comparison results are compressed and output in compressed pass/fail output signals OUTPUTS at 30 to integrated circuit tester 22. Integrated circuit tester 22 receives compressed pass/fail output signals OUTPUTS at 30 from integrated circuit 24.

FIG. 2 is a diagram illustrating one embodiment of test circuit 36 that includes an address controlled data pattern generator (ACDPG) 60 and a compare circuit 62. ACDPG 60 is electrically coupled to address signal input pads 40 (shown in FIG. 1) via internal address signal paths 46 and to mask signal input pad 42 (shown in FIG. 1) via internal mask signal path 48. ACDPG 60 receives address signals ADDR at 26 via address signal input pads 40 and internal address signal paths 46. ACDPG 60 receives mask signals MASK at 28 via mask signal input pad 42 and internal mask signal path 48.

ACDPG 60 selects bits of the row address and the column address in address signals ADDR at 26 based on mask bits in the mask signals MASK at 28 and generates test data TDATA based on the selected bits of the row address and the column address. ACDPG 60 is electrically coupled to memory and memory read/write logic 38 via write data paths 52 and to compare circuit 62 via data signal path 64. ACDPG 60 provides the generated test data TDATA to memory and memory read/write logic 38 via write data paths 52. Write logic in memory and memory read/write logic 38 writes test data TDATA at 52 into the memory in memory and memory read/write logic 38.

ACDPG 60 provides generated test data TDATA to compare circuit 62 via data signal path 64. Compare circuit 62 is electrically coupled to memory and memory read/write logic 38 via read data paths 54 and to output signal pads 44 via internal output signal paths 50. Test circuit 36 reads the memory via read logic in memory and memory read/write logic 38 and compare circuit 62 receives the read data RDATA via read data paths 54. Compare circuit 62 compares test data TDATA received from ACDPG 60 to the read data RDATA and provides pass/fail comparison results, which are compressed and output in compressed pass/fail output signals OUTPUTS at 50.

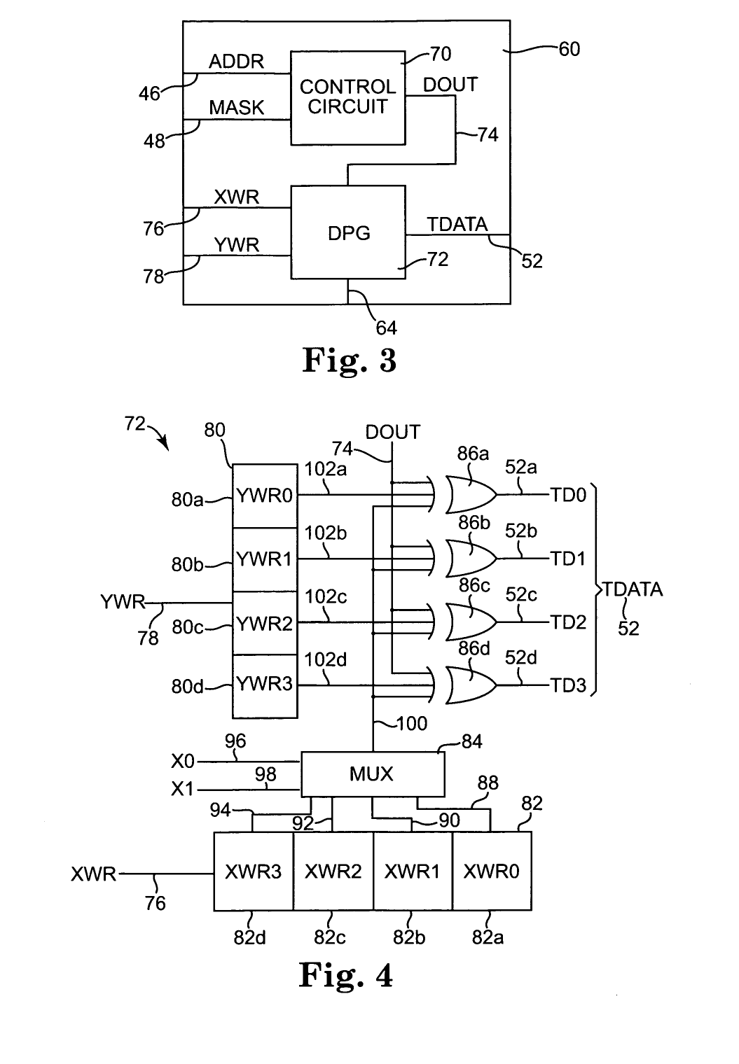

FIG. 3 is a diagram illustrating one embodiment of an ACDPG 60 that includes a control circuit 70 and a data pattern generator (DPG) 72. Control circuit 70 is electrically coupled to DPG 72 via control signal path 74. Control circuit 70 is electrically coupled to address signal input pads 40 (shown in FIG. 1) via internal address signal paths 46 and to mask signal input pad 42 (shown in FIG. 1) via internal mask signal path 48. Control circuit 70 receives address signals ADDR at 26 via address signal input pads 40 and internal address signal paths 46. Control circuit 70 receives mask signals MASK at 28 via mask signal input pad 42 and internal mask signal path 48. In one embodiment, control circuit 70 only receives a limited number of bits of the row address and/or the column address.

Control circuit 70 receives bits of the row address and the column address in address signals ADDR at 46 and masks off received bits based on mask bits received in the mask signals MASK at 48. Unmasked or selected bits are combined to provide a control signal DOUT at 74. In one embodiment, control circuit 70 performs an AND function on each of the received bits of the. row address and the column address and a corresponding one of the mask bits. In one embodiment, control circuit 70 performs an EXCLUSIVE-OR function on the selected bits to provide control signal DOUT at 74.

DPG 72 is electrically coupled to row write data signal paths 76 and to column write data signal paths 78. DPG 72 receives row write data XWR via row write data signal paths 76 and column write data YWR via column write data signal paths 78. In one embodiment, row write data XWR at 76 is provided via input pads from an external device, such as integrated circuit tester 22. In one embodiment, column write data YWR at 78 is provided via input pads from an external device, such as integrated circuit tester 22. In one embodiment, row write data XWR at 76 is provided via a pattern generator in integrated circuit 24. In one embodiment, column write data YWR at 78 is provided via a pattern generator in integrated circuit 24. In other embodiments, row write data XWR at 76 and column write data YWR at 78 are provided via any suitable circuitry, including latches and/or registers in integrated circuit 24 and hard coded circuitry in integrated circuit 24.

DPG 72 combines row write data XWR at 76, column write data YWR at 78, and control signal DOUT at 74 to provide test data TDATA based on the selected bits of the row address and the column address. In one embodiment, DPG 72 performs an EXCLUSIVE-OR function on each of the bits of column write data YWR at 78 and control signal DOUT at 74. In one embodiment, DPG 72 performs an EXCLUSIVE-OR function on each of the bits of row write data XWR at 76 and control signal DOUT at 74. In one embodiment, DPG 72 performs an EXCLUSIVE-OR function on each of the bits of column write data YWR at 78 and each of the bits of row write data XWR at 76 to obtain a data pattern result and DPG 72 performs another EXCLUSIVE-OR function on each of the bits of the data pattern result and control signal DOUT at 74 to provide test data TDATA. In other embodiments, DPG 72 performs any suitable function or functions on any suitable data and control signal DOUT at 74 to provide test data TDATA.

DPG 72 is electrically coupled to memory and memory read/write logic 38 via write data paths 52 and to compare circuit 62 via data signal path 64. DPG 72 provides test data TDATA at 52 to memory and memory read/write logic 38 via write data paths 52. Write logic in memory and memory read/write logic 38 writes the test data TDATA at 52 into the memory in memory and memory read/write logic 38. Also, DPG 72 provides test data TDATA at 52 to compare circuit 62 via data signal path 64. In one embodiment, DPG 72 provides test data TDATA to compare circuit 62 as the test data TDATA is generated. In one embodiment, compare circuit 62 stores the received test data TDATA and compares the stored test data TDATA to data read from the memory. In one embodiment, DPG 72 stores the test data TDATA and provides the test data TDATA to compare circuit 62, which compares the received test data TDATA to data read from the memory.

FIG. 4 is a diagram illustrating one embodiment of a DPG 72 that provides four bits of test data TD0 at 52a, TD1 at 52b, TD2 at 52c, and TD3 at 52d in test data TDATA at 52. DPG 72 provides the four bits of test data TD0 at 52a, TD1 at 52b, TD2 at 52c, and TD3 at 52d in parallel. The four bits of test data TD0 at 52a, TD1 at 52b, TD2 at 52c, and TD3 at 52d can be written into the memory in any suitable number of locations. In one embodiment, the four bits of test data TD0 at 52a, TD1 at 52b, TD2 at 52c, and TD3 at 52d are written into four different locations in the memory, such that sixteen bits of data are written into the memory based on each group of four parallel bits of test data TD0 at 52a, TD1 at 52b, TD2 at 52c, and TD3 at 52d.

DPG 72 includes a column write data register 80, a row write data register 82, a multiplexer 84, and four three-input EXCLUSIVE-OR circuits 86a-86d. The outputs of the four three-input EXCLUSIVE-OR circuits 86a-86d provide the four bits of test data TD0 at 52a, TD1 at 52b, TD2 at 52c, and TD3 at 52d. The output of three-input EXCLUSIVE-OR circuit 86a provides test data TD0 at 52a. The output of three-input EXCLUSIVE-OR circuit 86b provides test data TD1 at 52b, the output of three-input EXCLUSIVE-OR circuit 86c provides test data TD2 at 52c, and the output of three-input EXCLUSIVE-OR circuit 86d provides test data TD3 at 52d. One input of each of the four three-input EXCLUSIVE-OR circuits 86a-86d is electrically coupled to control circuit 70 via control signal path 74.

Column write data register 80 includes four column write data registers 80a-80d. Column write data register 80 is electrically coupled to column write data signal paths 78 and receives column write data YWR (YWR0-YWR3) via column write data signal paths 78. Column write data registers 80a-80d receive and store the column write data bits YWR0, YWR1, YWR2, and YWR3. Column write data register 80a stores column write data bit YWR0, column write data register 80b stores column write data bit YWR1, column write data register 80c stores column write data bit YWR2, and column write data register 80d stores column write data bit YWR3.

Column write data register 80 is electrically coupled to each of the four three-input EXCLUSIVE-OR circuits 86a-86d. Column write data register 80a is electrically coupled to one input of EXCLUSIVE-OR circuit 86a via column write data line 102a and provides column write data bit YWR0 to EXCLUSIVE-OR circuit 86a via column write data line 102a. Column write data register 80b is electrically coupled to one input of EXCLUSIVE-OR circuit 86b via column write data line 102b and provides column write data bit YWR1 to EXCLUSIVE-OR circuit 86b via column write data line 102b. Column write data register 80c is electrically coupled to one input of EXCLUSIVE-OR circuit 86c via column write data line 102c and provides column write data bit YWR2 to EXCLUSIVE-OR circuit 86c via column write data line 102c. Column write data register 80d is electrically coupled to one input of EXCLUSIVE-OR circuit 86d via column write data line 102d and provides column write data bit YWR3 to EXCLUSIVE-OR circuit 86d via column write data line 102d.

Row write data register 82 includes four row write data registers 82a-82d. Row write data register 82 is electrically coupled to row write data signal paths 76 and receives row write data XWR (XWR0-XWR3) via row write data signal paths 76. Row write data registers 82a-82d receive and store the four row write data bits XWR0, XWR1, XWR2, and XWR3. Row write data register 82a stores row write data bit XWR0, row write data register 82b stores row write data bit XWR1, row write data register 82c stores row write data bit XWR2, and row write data register 82d stores row write data bit XWR3.

Multiplexer 84 is controlled to select one of the four row write data bits XWR0, XWR1, XWR2, and XWR3 and provide the selected bit to the four three-input EXCLUSIVE-OR circuits 86a-86d. Multiplexer 84 is electrically coupled to row write data register 82. Row write data register 82a is electrically coupled to one input of multiplexer 84 via row write data line 88, row write data register 82b is electrically coupled to another input of multiplexer 84 via row write data line 90, row write data register 82c is electrically coupled to another input of multiplexer 84 via row write data line 92, and row write data register 82d is electrically coupled to another input of multiplexer 84 via row write data line 94. Also, multiplexer 84 is electrically coupled to address lines 96 and 98 and receives the two least significant bits of the row address X0 at 96 and X1 at 98. In addition, multiplexer 84 is electrically coupled to an input on each of the four three-input EXCLUSIVE-OR circuits 86a-86d via multiplexer output path 100.

In operation, DPG 72 receives column write data YWR0-YWR3 via column write data signal paths 78 and row write data XWR0-XWR3 via row write data signal paths 76. Also, control circuit 70 receives mask signal MASK at 48 and provides control signal DOUT at 74 to each of the four three-input EXCLUSIVE-OR circuits 86a-86d.

Column write data register 80a provides column write data bit YWR0 to EXCLUSIVE-OR circuit 86a via column write data line 102a, column write data register 80b provides column write data bit YWR1 to EXCLUSIVE-OR circuit 86b via column write data line 102b, column write data register 80c provides column write data bit YWR2 to EXCLUSIVE-OR circuit 86c via column write data line 102c, and column write data register 80d provides column write data bit YWR3 to EXCLUSIVE-OR circuit 86d via column write data line 102d.

Row write data register 82a provides row write data bit XWR0 to multiplexer 84 via row write data line 88, row write data register 82b provides row write data bit XWR1 to multiplexer 84 via row write data line 90, row write data register 82c provides row write data bit XWR2 to multiplexer 84 via row write data line 92, and row write data register 82d provides row write data bit XWR3 to multiplexer 84 via row write data line 94.

Multiplexer 84 receives the two least significant bits of the row address, X0 at 96 and X1 at 98, and selects one bit of row write data XWR0-XWR3. The selected bit of row write data XWR0-XWR3 is provided to each of the four three-input EXCLUSIVE-OR circuits 86a-86d, which provide the four bits of test data TD0 at 52a, TD1 at 52b, TD2 at 52c, and TD3 at 52d in test data TDATA at 52. Four bits of test data are provided for each of four row addresses given by the two least significant bits of the row address, X0 at 96 and X1 at 98. Thus, the test data TDATA at 52 is four columns wide and four rows deep.

Each of the four three-input EXCLUSIVE-OR circuits 86a-86d provides one of the four bits of test data TD0 at 52a, TD1 at 52b, TD2 at 52c, and TD3 at 52d in test data TDATA at 52. If the number of high logic levels in the three inputs of one of the four three-input EXCLUSIVE-OR circuits 86a-86d is odd, the three-input EXCLUSIVE-OR circuit provides a high logic level output in test data signal TDATA at 52. If the number of high logic levels in the three inputs of one of the four three-input EXCLUSIVE-OR circuits 86a-86d is even, the three-input EXCLUSIVE-OR circuit provides a low logic level output in the test data signal TDATA at 52.

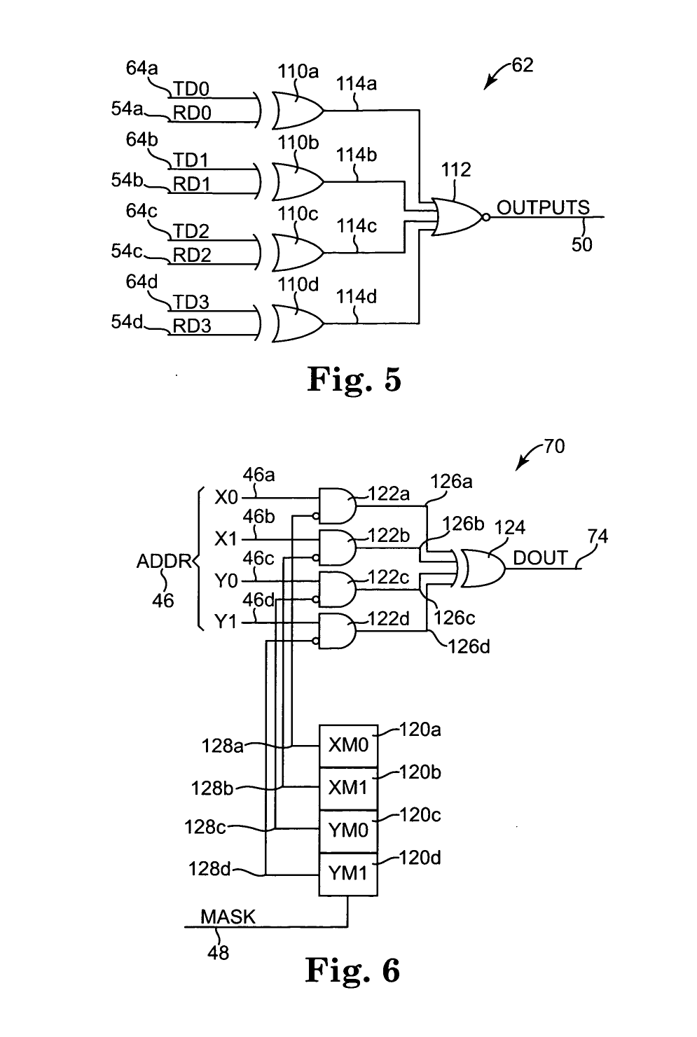

FIG. 5 is a diagram illustrating one embodiment of a compare circuit 62. ACDPG 60 (shown in FIG. 2) includes DPG 72 (shown in FIG. 3), which provides test data TDATA to compare circuit 62 via data signal path 64. Test circuit 36 reads the memory via read logic in memory and memory read/write logic 38 and compare circuit 62 receives the read data RDATA via read data paths 54. Compare circuit 62 compares the test data TDATA at 64 to the read data RDATA at 54 and provides pass/fail comparison results, which are compressed and output in compressed pass/fail output signals OUTPUTS at 50.

In one embodiment, DPG 72 generates and provides test data TDATA to compare circuit 62 substantially as compare circuit 62 receives read data RDATA. In one embodiment, DPG 72 generates and provides test data TDATA to compare circuit 62 substantially as memory and memory read/write logic 38 writes the test data TDATA into the memory. In one embodiment, compare circuit 62 stores received test data TDATA and compares the stored test data TDATA to read data RDATA from the memory. In one embodiment, DPG 72 stores test data TDATA and provides the stored test data TDATA to compare circuit 62 substantially as compare circuit 62 receives read data RDATA.

Compare circuit 62 includes four two-input EXCLUSIVE-OR circuits 110a-110d and a NOR circuit 112. The output of each of the four two-input EXCLUSIVE-OR circuits 110a-110d is electrically coupled to an input of NOR circuit 112 via output paths 114a-114d, respectively. NOR circuit 112 is electrically coupled to output signal pads 44 via internal output signal paths 50. The output of NOR circuit 112 provides compressed pass/fail output signals OUTPUTS at 50.

The four two-input EXCLUSIVE-OR circuits 110a-110d are electrically coupled to DPG 72 via data signal paths 64a-64d. EXCLUSIVE-OR circuit 110a is electrically coupled to DPG 72 via data signal path 64a, EXCLUSIVE-OR circuit 110b is electrically coupled to DPG 72 via data signal path 64b, EXCLUSIVE-OR circuit 110c is electrically coupled to DPG 72 via data signal path 64c, and EXCLUSIVE-OR circuit 110d is electrically coupled to DPG 72 via data signal path 64d.

Also, the four two-input EXCLUSIVE-OR circuits 110a-110d are electrically coupled to memory and memory read/write logic 38 via read data paths 54a-54d. EXCLUSIVE-OR circuit 110a is electrically coupled to memory and memory read/write logic 38 via read data path 54a, EXCLUSIVE-OR circuit 110b is electrically coupled to memory and memory read/write logic 38 via read data path 54b, EXCLUSIVE-OR circuit 110c is electrically coupled to memory and memory read/write logic 38 via read data path 54c, and EXCLUSIVE-OR circuit 110d is electrically coupled to memory and memory read/write logic 38 via read data path 54d.

The four two-input EXCLUSIVE-OR circuits 110a-110d receive test data TDATA at 64 (TD0-TD3) and read data RDATA at 54 (RD0-RD3). EXCLUSIVE-OR circuit 110a receives read data RD0 at 54a and test data TD0 at 64a, EXCLUSIVE-OR circuit 110b receives read data RD1 at 54b and test data TD1 at 64b, EXCLUSIVE-OR circuit 110c receives read data RD2 at 54c and test data TD2 at 64c, EXCLUSIVE-OR circuit 110d receives read data RD3 at 54d and test data TD3 at 64d.

Each of the four two-input EXCLUSIVE-OR circuits 110a-110d provides a pass/fail comparison result to NOR circuit 112. If the two inputs received by an EXCLUSIVE-OR circuit are the same, the EXCLUSIVE-OR circuit provides a low logic level signal that indicates a pass. If the two inputs received by an EXCLUSIVE-OR circuit are different, the EXCLUSIVE-OR circuit provides a high logic level that indicates a fail. NOR circuit 112 receives the four pass/fail comparison results and compresses the results into one pass/fail output signal. If all four comparison results are at a low logic level, NOR circuit 112 provides a high logic level that indicates a pass. If any one of the four comparison results is at a high logic level, NOR circuit 112 provides a low logic level that indicates one of the four failed.

In operation, DPG 72 provides test data TD0-TD3 to compare circuit 62 via data signal paths 64a-64d. Test circuit 36 reads the memory via read logic in memory and memory read/write logic 38 and compare circuit 62 receives the read data RD0-RD3 via read data paths 54a-54d. The four two-input EXCLUSIVE-OR circuits 110a-110d compare the received test data TD0-TD3 and read data RD0-RD3 and provide pass/fail comparison results to NOR circuit 112, which compresses the comparison results and outputs a compressed pass/fail result in output signals OUTPUTS at 50.

FIG. 6 is a diagram illustrating one embodiment of a control circuit 70. Control circuit 70 receives address signals ADDR via address signal input pads 40 and internal address signal paths 46. Also, control circuit 70 receives mask signals MASK via mask signal input pad 42 and internal mask signal path 48. Control circuit 70 receives bits of the row address and bits of the column address in address signals ADDR at 46 and masks off received address bits based on mask bits received in mask signals MASK at 48. Unmasked or selected bits are combined to provide control signal DOUT at 74.

Control circuit 70 includes four mask registers 120a-120d, four AND gates 122a-122d, and an EXCLUSIVE-OR circuit 124. The output of each of the four AND gates 122a-122d is electrically coupled to an input of EXCLUSIVE-OR circuit 124 via AND gate output paths 126a-126d, respectively. EXCLUSIVE-OR circuit 124 is electrically coupled to DPG 72 via control signal path 74 and provides data output signal DOUT at 74.

The output of each of the four mask registers 120a-120d is electrically coupled to an inverted input of one of the four AND gates 122a-122d. The output of mask register 120a is electrically coupled to an inverted input of AND gate 122a via mask bit data path 128a, the output of mask register 120b is electrically coupled to an inverted input of AND gate 122b via mask bit data path 128b, the output of mask register 120c is electrically coupled to an inverted input of AND gate 122c via mask bit data path 128c, and the output of mask register 120d is electrically coupled to an inverted input of AND gate 122d via mask bit data path 128d.

The four mask registers 120a-120d receive mask signals MASK at 48 and store mask bits XM0, XM1, YM0, and YM1. Mask register 120a receives and stores mask bit XM0, mask register 120b receives and stores mask bit XM1, mask register 120c receives and stores mask bit YM0, and mask register 120d receives and stores mask bit YM1. The four AND gates 122a-122d receive address signals ADDR at 46. At one input AND gate 122a receives address signal X0 at 46a, at one input AND gate 122b receives address signal X1 at 46b, at one input AND gate 122c receives address signal Y0 at 46c, and at one input AND gate 122d receives address signal Y1 at 46d.

The four mask registers 120a-120d provide the mask bits XM0, XM1, YM0, and YM1 to AND gates 122a-122d to mask off or select address signals X0, X1, Y0, and Y1. Mask bit XM0 masks off or selects address signal X0, mask bit XM1 masks off or selects address signal X1, mask bit YM0 masks off or selects address signal Y0, and mask bit YM1 masks off or selects address signal Y1. Each of the mask bits XM0, XM1, YM0, and YM1 is a high logic level to mask off the respective address bit X0, X1, Y0, and Y1 and a low logic level to select the respective address bit X0, X1, Y0, and Y1.

In operation, mask registers 120a-120d are loaded with mask bits XM0, XM1, YM0, and YM1, respectively. The AND gates 122a-122d receive mask bits XM0, XM1, YM0, and YM1, respectively, and row address bits X0 at 46a and X1 at 46b and column address bits Y0 at 46c and Y1 at 46d. The AND gates 122a-122d mask off the received address signals X0, X1, Y0, and Y1 based on mask bits XM0, XM1, YM0, and YM1. The AND gates 122a-122d provide results to EXCLUSIVE-OR circuit 124. Unmasked or selected bits are combined via EXCLUSIVE-OR circuit 124, which provides control signal DOUT at 74. If an odd number of the inputs of EXCLUSIVE-OR circuit 124 are high logic levels, EXCLUSIVE-OR circuit 124 provides a high logic level in control signal DOUT at 74. If an even number of the inputs of EXCLUSIVE-OR circuit 124 are high logic levels, EXCLUSIVE-OR circuit 124 provides a low logic level in control signal DOUT at 74. DPG 72 combines row write data XWR at 76, column write data YWR at 78, and control signal DOUT at 74 to provide test data TDATA based on the selected bits of the row address and the column address.

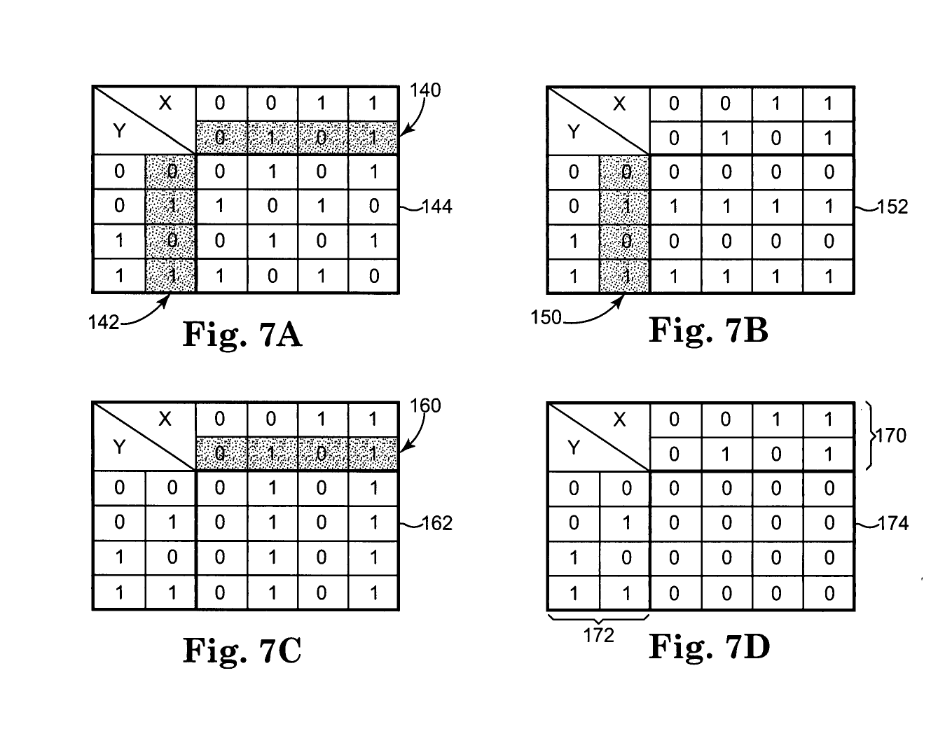

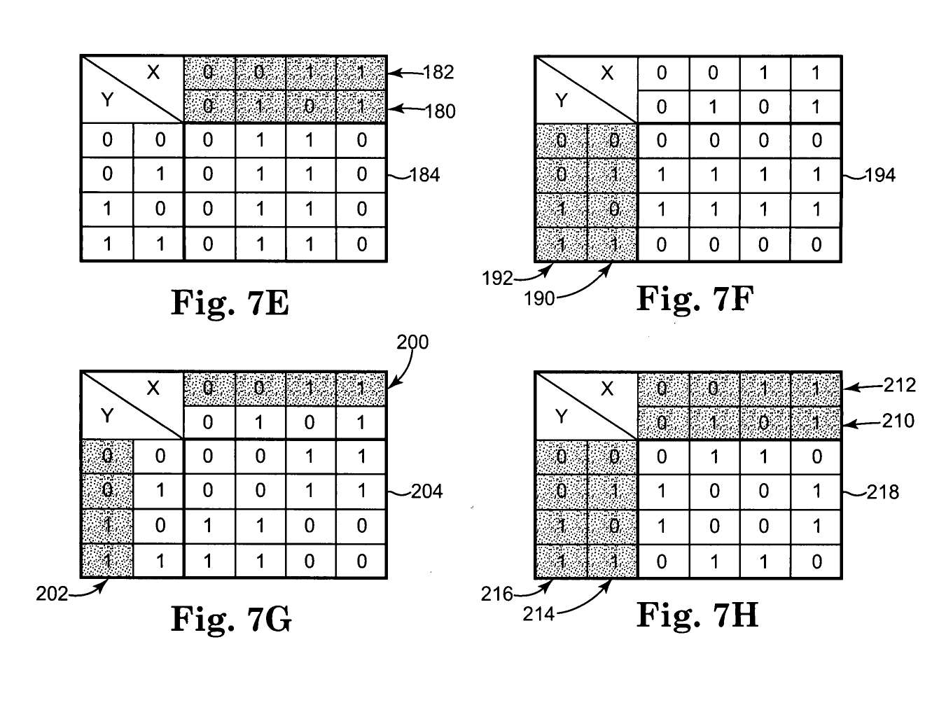

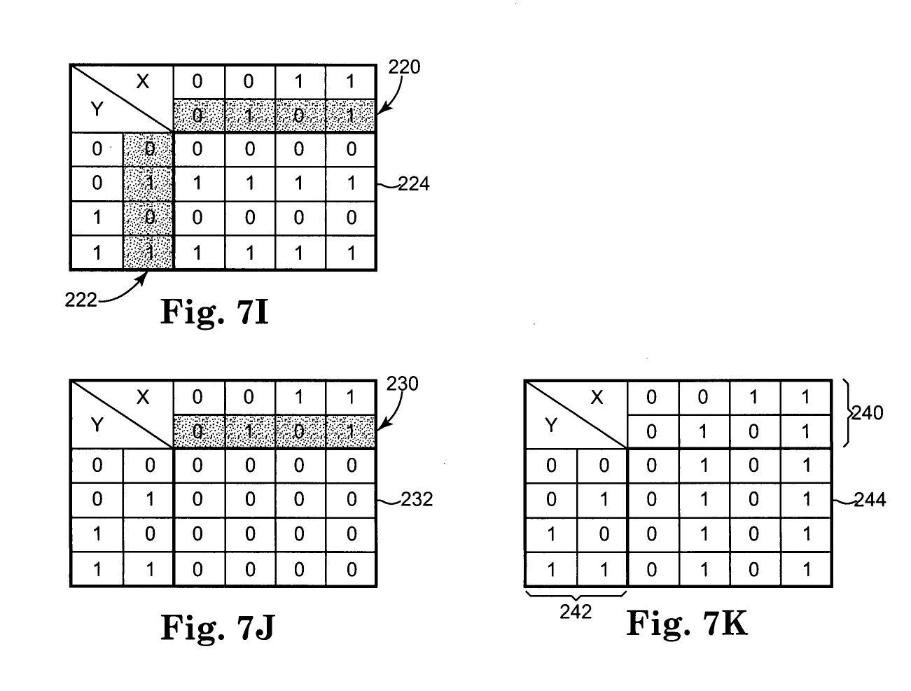

FIGS. 7A-7K are truth tables illustrating the operation of one embodiment of ACDPG 60. FIG. 7A illustrates the operation of ACDPG 60 including control circuit 70 that selects the least significant bit of row address X0 at 140 and the least significant bit of column address Y0 at 142. Control circuit 70 combines the selected bits X0 at 140 and Y0 at 142 via EXCLUSIVE-OR circuit 124 to provide control signal DOUT at 74.

Control circuit 70 receives mask signal MASK at 48, where mask registers 120a-120d receive a hexadecimal A (1010) nibble value. Mask register 120a receives and stores a low logic level or zero XM0 mask bit, mask register 120b receives and stores a high logic level or one XM1 mask bit, mask register 120c receives and stores a low logic level or zero YM0 mask bit, and mask register 120d receives and stores a high logic level or one YM1 mask bit.

The AND gates 122b and 122d receive ones via mask bits XM1 and YM1 to mask off row address bit X1 and column address bit Y1. The AND gates 122a and 122c receive zeroes via mask bits XM0 and YM0 to select row address bit X0 and column address bit Y0. The selected bits X0 at 140 and Y0 at 142 are combined via EXCLUSIVE-OR circuit 124 to provide a high logic value in control signal DOUT at 74 if only one of the two selected bits is a high logic value and a low logic value in control signal DOUT at 74 if both of the selected bits are a high logic value or both of the selected bits are a low logic value.

DPG 72 receives all zeroes in column write data YWR0-YWR3 via column write data signal paths 78 and all zeroes in row write data XWR0-XWR3 via row write data signal paths 76. The four EXCLUSIVE-OR circuits 86a-86d receive all zeroes in column write data YWR0-YWR3 and a zero from multiplexer 84 and row write data XWR0-XWR3 for each value of the least two significant bits of the row address X0 and X1. Also, the four EXCLUSIVE-OR circuits 86a-86d receive control signal DOUT at 74 and provide test data TDATA at 52.

If control signal DOUT at 74 is a zero, then all four test data bits TD0-TD3 are zeros. If control signal DOUT at 74 is a one, then all four test data bits TD0-TD3 are ones. This provides the checkerboard pattern at 144, where test data bits TD0-TD3 are represented by a single 0 or 1 value.

FIG. 7B illustrates the operation of ACDPG 60 including control circuit 70 that selects the least significant bit of column address Y0 at 150. Control circuit 70 receives mask signal MASK at 48, where mask registers 120a-120d receive a hexadecimal B (1011) nibble value. Mask register 120a receives and stores a high logic level or one XM0 mask bit, mask register 120b receives and stores a high logic level or one XM1 mask bit, mask register 120c receives and stores a low logic level or zero YM0 mask bit, and mask register 120d receives and stores a high logic level or one YM1 mask bit.

The AND gates 122a, 122b, and 122d receive ones via mask bits XM0, XM1, and YM1 to mask off row address bits X0 and X1 and column address bit Y1. The AND gate 122c receives a zero via mask bit YM0 to select column address bit Y0. The selected bit Y0 at 150 is provided via EXCLUSIVE-OR circuit 124 to provide a high logic value in control signal DOUT at 74 if bit Y0 at 150 is a high logic value and a low logic value in control signal DOUT at 74 if bit Y0 at 150 is a low logic value.

DPG 72 receives all zeroes in column write data YWR0-YWR3 via column write data signal paths 78 and all zeroes in row write data XWR0-XWR3 via row write data signal paths 76. The four EXCLUSIVE-OR circuits 86a-86d receive all zeroes in column write data YWR0-YWR3 and a zero via multiplexer 84 and row write data XWR0-XWR3 for each value of the least two significant bits of the row address X0 and X1. Also, the four EXCLUSIVE-OR circuits 86a-86d receive control signal DOUT at 74. If control signal DOUT at 74 is a zero, then all four test data bits TD0-TD3 are zeros. If control signal DOUT at 74 is a one, then all four test data bits TD0-TD3 are ones. This provides the Y parity pattern at 152, where test data bits TD0-TD3 are represented by a single 0 a or 1 value.

FIG. 7C illustrates the operation of ACDPG 60 including control circuit 70 that selects the least significant bit of row address X0 at 160. Control circuit 70 receives mask signal MASK at 48, where mask registers 120a-120d receive a hexadecimal E (1110) nibble value. Mask register 120a receives and stores a low logic level or zero XM0 mask bit, mask register 120b receives and stores a high logic level or one XM1 mask bit, mask register 120c receives and stores a high logic level or one YM0 mask bit, and mask register 120d receives and stores a high logic level or one YM1 mask bit.

The AND gates 122b, 122c, and 122d receive ones via mask bits XM1, YM0, and YM1 to mask off row address bit X1 and column address bits Y0 and Y1. The AND gate 122a receives a zero via mask bit XM0 to select row address bit X0. The selected bit X0 at 160 is provided via EXCLUSIVE-OR circuit 124 to provide a high logic value in control signal DOUT at 74 if bit X0 at 160 is a high logic value and a low logic value in control signal DOUT at 74 if bit X0 at 160 is a low logic value.

DPG 72 receives all zeroes in column write data YWR0-YWR3 via column write data signal paths 78 and all zeroes in row write data XWR0-XWR3 via row write data signal paths 76. The four EXCLUSIVE-OR circuits 86a-86d receive all zeroes in column write data YWR0-YWR3 and a zero via multiplexer 84 and row write data XWR0-XWR3 for each value of the least two significant bits of the row address X0 and X1. Also, the four EXCLUSIVE-OR circuits 86a-86d receive control signal DOUT at 74. If control signal DOUT at 74 is a zero, then all four test data bits TD0-TD3 are zeros. If control signal DOUT at 74 is a one, then all four test data bits TD0-TD3 are ones. This provides the X parity pattern at 162, where test data bits TD0-TD3 are represented by a single 0 or 1 value.

FIG. 7D illustrates the operation of ACDPG 60 including control circuit 70 that masks off row address bits at 170 and column address bits at 172. Control circuit 70 receives mask signal MASK at 48, where mask registers 120a-120d receive a hexadecimal F (1111) nibble value. Mask register 120a receives and stores a high logic level or one XM0 mask bit, mask register 120b receives and stores a high logic level or one XM1 mask bit, mask register 120c receives and stores a high logic level or one YM0 mask bit, and mask register 120d receives and stores a high logic level or one YM1 mask bit.

The AND gates 122a-122d receive ones via mask bits XM0, XM1, YM0, and YM1 to mask off row address bits X0 and X1 and column address bits Y0 and Y1. Since none of the row address bits at 170 or column address bits at 172 are selected, EXCLUSIVE-OR circuit 124 receives all zeroes and provides a low logic value in control signal DOUT at 74.

DPG 72 receives all zeroes in column write data YWR0-YWR3 via column write data signal paths 78 and all zeroes in row write data XWR0-XWR3 via row write data signal paths 76. The four EXCLUSIVE-OR circuits 86a-86d receive all zeroes in column write data YWR0-YWR3 and a zero via multiplexer 84 and row write data XWR0-XWR3 for each value of the least two significant bits of the row address X0 and X1. Also, the four EXCLUSIVE-OR circuits 86a-86d receive all zeroes in control signal DOUT at 74. Thus, all zeroes are provided at 174, where TD0-TD3 are represented by a single 0 value.

FIG. 7E illustrates the operation of ACDPG 60 including control circuit 70 that selects the two least significant bits of row address X0 at 180 and X1 at 182. Control circuit 70 receives mask signal MASK at 48, where mask registers 120a-120d receive a hexadecimal C (1100) nibble value. Mask register 120a receives and stores a low logic level or zero XM0 mask bit, mask register 120b receives and stores a low logic level or zero XM1 mask bit, mask register 120c receives and stores a high logic level or one YM0 mask bit, and mask register 120d receives and stores a high logic level or one YM1 mask bit.

The AND gates 122c and 122d receive ones via mask bits YM0 and YM1 to mask off column address bits Y0 and Y1. The AND gates 122a and 122b receive zeroes via mask bits XM0 and XM1 to select row address bits X0 and X1. The selected bits X0 at 180 and X1 at 182 are combined via EXCLUSIVE-OR circuit 124 to provide a high logic value in control signal DOUT at 74 if only one of the bits X0 at 180 and X1 at 182 is a high logic value and a low logic value in control signal DOUT at 74 if both of the bits X0 at 180 and X1 at 182 are high logic values or both of the bits X0 at 180 and X1 at 182 are low logic values.

DPG 72 receives all zeroes in column write data YWR0-YWR3 via column write data signal paths 78 and all zeroes in row write data XWR0-XWR3 via row write data signal paths 76. The four EXCLUSIVE-OR circuits 86a-86d receive all zeroes in column write data YWR0-YWR3 and a zero via multiplexer 84 and row write data XWR0-XWR3 for each value of the least two significant bits of row address X0 and X1. Also, the four EXCLUSIVE-OR circuits 86a-86d receive control signal DOUT at 74. If control signal DOUT at 74 is a zero, then all four test data bits TD0-TD3 are zeros. If control signal DOUT at 74 is a one, then all four test data bits TD0-TD3 are ones. This provides the double row bar pattern at 184, where test data bits TD0-TD3 are represented by a single 0 or 1 value.

FIG. 7F illustrates the operation of ACDPG 60 including control circuit 70 that selects the two least significant bits of column address Y0 at 190 and Y1 at 192. Control circuit 70 receives mask signal MASK at 48, where mask registers 120a-120d receive a hexadecimal 3 (0011) nibble value. Mask register 120a receives and stores a high logic level or one XM0 mask bit, mask register 120b receives and stores a high logic level or one XM1 mask bit, mask register 120c receives and stores a low logic level or zero YM0 mask bit, and mask register 120d receives and stores a low logic level or zero YM1 mask bit.

The AND gates 122a and 122b receive ones via mask bits XM0 and XM1 to mask off row address bits X0 and X1. The AND gates 122c and 122d receive zeroes via mask bits YM0 and YM1 to select column address bits Y0 and Y1. The selected bits Y0 at 190 and Y1 at 192 are combined via EXCLUSIVE-OR circuit 124 to provide a high logic value in control signal DOUT at 74 if only one of the bits Y0 at 190 and Y1 at 192 is a high logic value and a low logic value in control signal DOUT at 74 if both of the bits Y0 at 190 and Y1 at 192 are high logic values or both of the bits Y0 at 190 and Y1 at 192 are low logic values.

DPG 72 receives all zeroes in column write data YWR0-YWR3 via column write data signal paths 78 and all zeroes in row write data XWR0-XWR3 via row write data signal paths 76. The four EXCLUSIVE-OR circuits 86a-86d receive all zeroes in column write data YWR0-YWR3 and a zero via multiplexer 84 and row write data XWR0-XWR3 for each value of the least two significant bits of row address X0 and X1. Also, the four EXCLUSIVE-OR circuits 86a-86d receive control signal DOUT at 74. If control signal DOUT at 74 is a zero, then all four test data bits TD0-TD3 are zeros. If control signal DOUT at 74 is a one, then all four test data bits TD0-TD3 are ones. This provides the double column bar pattern at 194, where test data bits TD0-TD3 are represented by a single 0 or 1 value.

FIG. 7G illustrates the operation of ACDPG 60 including control circuit 70 that selects bit X1 at 200 of the row address and bit Y1 at 202 of the column address. Control circuit 70 receives mask signal MASK at 48, where mask registers 120a-120d receive a hexadecimal 5 (0101) nibble value. Mask register 120a receives and stores a high logic level or one XM0 mask bit, mask register 120b receives and stores a low logic level or zero XM1 mask bit, mask register 120c receives and stores a high logic level or one YM0 mask bit, and mask register 120d receives and stores a low logic level or zero YM1 mask bit.

The AND gates 122a and 122c receive ones via mask bits XM0 and YM0 to mask off row address bit X0 and column address bit Y0. The AND gates 122b and 122d receive zeroes via mask bits XM1 and YM1 to select row address bit X1 and column address bit Y1. The selected bits X1 at 200 and Y1 at 202 are combined via EXCLUSIVE-OR circuit 124 to provide a high logic value in control signal DOUT at 74 if only one of the bits X1 at 200 and Y1 at 202 is a high logic value and a low logic value in control signal DOUT at 74 if both of the bits X1 at 200 and Y1 at 202 are high logic values or both of the bits X1 at 200 and Y1 at 202 are low logic values.

DPG 72 receives all zeroes in column write data YWR0-YWR3 via column write data signal paths 78 and all zeroes in row write data XWR0-XWR3 via row write data signal paths 76. The four EXCLUSIVE-OR circuits 86a-86d receive all zeroes in column write data YWR0-YWR3 and a zero via multiplexer 84 and row write data XWR0-XWR3 for each value of the least two significant bits of row address X0 and X1. Also, the four EXCLUSIVE-OR circuits 86a-86d receive control signal DOUT at 74. If control signal DOUT at 74 is a zero, then all four test data bits TD0-TD3 are zeros. If control signal DOUT at 74 is a one, then all four test data bits TD0-TD3 are ones. This provides the double checkerboard pattern at 204, where test data bits TD0-TD3 are represented by a single 0 or 1 value.

FIG. 7H illustrates the operation of ACDPG 60 including control circuit 70 that selects bits X0 at 210 and X1 at 212 of the row address and bits Y0 at 214 and Y1 at 216 of the column address. Control circuit 70 receives mask signal MASK at 48, where mask registers 120a-120d receive a hexadecimal 0 (0000) nibble value. Mask register 120a receives and stores a low logic level or zero XM0 mask bit, mask register 120b receives and stores a low logic level or zero XM1 mask bit, mask register 120c receives and stores a low logic level or zero YM0 mask bit, and mask register 120d receives and stores a low logic level or zero YM1 mask bit.

The AND gates 122a-122d receive zeroes via mask bits XM0, XM1, YM0, and YM1 to select row address bits X0 and X1 and column address bits Y0 and Y1. The selected bits X0 at 210, X1 at 212, Y0 at 214, and Y1 at 216 are combined via EXCLUSIVE-OR circuit 124 to provide a high logic value in control signal DOUT at 74 if an odd number of the bits X0 at 210, X1 at 212, Y0 at 214, and Y1 at 216 are a high logic value and a low logic value in control signal DOUT at 74 if an even number of the bits X0 at 210, X1 at 212, Y0 at 214, and Y1 at 216 are high logic values or if all of the bits X0 at 210, X1 at 212, Y0 at 214, and Y1 at 216 are low logic values.

DPG 72 receives all zeroes in column write data YWR0-YWR3 via column write data signal paths 78 and all zeroes in row write data XWR0-XWR3 via row write data signal paths 76. The four EXCLUSIVE-OR circuits 86a-86d receive all zeroes in column write data YWR0-YWR3 and a zero via multiplexer 84 and row write data XWR0-XWR3 for each value of the least two significant bits of row address X0 and X1. Also, the four EXCLUSIVE-OR circuits 86a-86d receive control signal DOUT at 74. If control signal DOUT at 74 is a zero, then all four test data bits TD0-TD3 are zeros. If control signal DOUT at 74 is a one, then all four test data bits TD0-TD3 are ones. This provides the double checkerboard pattern at 218, where test data bits TD0-TD3 are represented by a single 0 or 1 value.

FIG. 7I illustrates the operation of ACDPG 60 including control circuit 70 that selects the least significant bit of row address X0 at 220 and the least significant bit of column address Y0 at 222. Also, DPG 72 receives a hexadecimal A (1010) in row write data XWR3-XWR0 via row write data signal paths 76.

Control circuit 70 receives mask signal MASK at 48, where mask registers 120a-120d receive a hexadecimal A (1010) nibble value. Mask register 120a receives and stores a low logic level or zero XM0 mask bit, mask register 120b receives and stores a high logic level or one XM1 mask bit, mask register 120c receives and stores a low logic level or zero YM0 mask bit, and mask register 120d receives and stores a high logic level or one YM1 mask bit.

The AND gates 122b and 122d receive ones via mask bits XM1 and YM1 to mask off row address bit X1 and column address bit Y1. The AND gates 122a and 122c receive zeroes via mask bits XM0 and YM0 to select row address bit X0 and column address bit Y0. The selected bits X0 at 220 and Y0 at 222 are combined via EXCLUSIVE-OR circuit 124 to provide a high logic value in control signal DOUT at 74 if only one of the two selected bits is a high logic value and a low logic value in control signal DOUT at 74 if both of the selected bits are a high logic value or both of the selected bits are a low logic value.

DPG 72 receives all zeroes in column write data YWR0-YWR3 via column write data signal paths 78 and a hexadecimal A (1010) in row write data XWR3-XWR0 via row write data signal paths 76. The four EXCLUSIVE-OR circuits 86a-86d receive all zeroes in column write data YWR0-YWR3. Also, the four EXCLUSIVE-OR circuits 86a-86d receive a zero from multiplexer 84 and row write data XWR3-XWR0 if the two least significant bits of the row address X1 and X0 are 00 or 10, respectively, and a one if the two least significant bits of the row address X1 and X0 are 01 or 11, respectively. Also, the four EXCLUSIVE-OR circuits 86a-86d receive control signal DOUT at 74, which results in the column bar pattern at 224, where test data bits TD0-TD3 are represented by a single 0 or 1 value.

FIG. 7J illustrates the operation of ACDPG 60 including control circuit 70 that selects the least significant bit of row address X0 at 230. Also, DPG 72 receives a hexadecimal A (1010) in row write data XWR3-XWR0 via row write data signal paths 76.

Control circuit 70 receives mask signal MASK at 48, where mask registers 120a-120d receive a hexadecimal E (1110) nibble value. Mask register 120a receives and stores a low logic level or zero XM0 mask bit, mask register 120b receives and stores a high logic level or one XM1 mask bit, mask register 120c receives and stores a high logic level or one YM0 mask bit, and mask register 120d receives and stores a high logic level or one YM1 mask bit.

The AND gates 122b, 122c, and 122d receive ones via mask bits XM1, YM0, and YM1 to mask off row address bit X1 and column address bits Y0 and Y1. The AND gate 122a receives a zero via mask bit XM0 to select row address bit X0. The selected bit X0 at 230 is received by EXCLUSIVE-OR circuit 124, which provides a high logic value in control signal DOUT at 74 if bit X0 at 230 is a high logic value and a low logic value in control signal DOUT at 74 if bit X0 at 230 is a low logic value.

DPG 72 receives all zeroes in column write data YWR0-YWR3 via column write data signal paths 78 and a hexadecimal A (1010) in row write data XWR3-XWR0 via row write data signal paths 76. The four EXCLUSIVE-OR circuits 86a-86d receive all zeroes in column write data YWR0-YWR3. Also, the four EXCLUSIVE-OR circuits 86a-86d receive a zero from multiplexer 84 and row write data XWR3-XWR0 if the two least significant bits of the row address X1 and X0 are 00 or 10, respectively, and a one if the two least significant bits of the row address X1 and X0 are 01 or 11, respectively. Also, the four EXCLUSIVE-OR circuits 86a-86d receive control signal DOUT at 74. This results in all zeroes at 232, where test data bits TD0-TD3 are represented by a single 0 value.

FIG. 7K illustrates the operation of ACDPG 60 including control circuit 70 that masks off row address bits at 240 and column address bits at 242. Also, DPG 72 receives a hexadecimal A (1010) in row write data XWR3-XWR0 via row write data signal paths 76.

Control circuit 70 receives mask signal MASK at 48, where mask registers 120a-120d receive a hexadecimal F (1111) nibble value. Mask register 120a receives and stores a high logic level or one XM0 mask bit, mask register 120b receives and stores a high logic level or one XM1 mask bit, mask register 120c receives and stores a high logic level or one YM0 mask bit, and mask register 120d receives and stores a high logic level or one YM1 mask bit.

The AND gates 122a-122d receive ones via mask bits XM0, XM1, YM0, and YM1 to mask off row address bits X0 and X1 and column address bits Y0 and Y1. Since none of the row address bits at 240 or column address bits at 242 are selected, EXCLUSIVE-OR circuit 124 receives all zeroes and provides a low logic value in control signal DOUT at 74.

DPG 72 receives all zeroes in column write data YWR0-YWR3 via column write data signal paths 78 and a hexadecimal A (1010) in row write data XWR3-XWR0 via row write data signal paths 76. The four EXCLUSIVE-OR circuits 86a-86d receive all zeroes in column write data YWR0-YWR3 and zeroes in control signal DOUT at 74. Also, the four EXCLUSIVE-OR circuits 86a-86d receive a zero from multiplexer 84 and row write data XWR3-XWR0 if the two least significant bits of the row address X1 and X0 are 00 or 10, respectively, and a one if the two least significant bits of the row address X1 and X0 are 01 or 11, respectively, which results in the row bar pattern at 244, where test data bits TD0-TD3 are represented by a single 0 or 1 value.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A random access memory, comprising:
input pads configured to receive a row address and a column address; and
a test circuit configured to receive the row address and the column address via the input pads and to receive mask bits, wherein the test circuit selects bits of the row address and the column address based on the mask bits and provides at least one test data bit based on the selected bits of the row address and the column address.

2. The random access memory of claim 1, wherein the test circuit comprises:
a mask register configured to store the received mask bits; and
a first circuit configured to mask off bits of the row address and the column address based on the mask bits to provide the selected bits.

3. The random access memory of claim 2, wherein the test circuit inverts data based on the selected bits to provide the at least one test data bit.

4. The random access memory of claim 1, wherein the test circuit comprises:
a data pattern generator that provides data; and
a first circuit configured to invert the data based on the number of the selected bits in one logic state.

5. The random access memory of claim 4, wherein the first circuit inverts the data if the number of logic high bits in the selected bits is odd and maintains the logic state of the data if the number of logic high bits in the selected bits is even.

6. The random access memory of claim 1, wherein the test circuit comprises:
a data pattern generator configured to receive data inputs; and
a first circuit configured to invert the data inputs based on the number of the selected bits in one logic state.

7. The random access memory of claim 6, wherein the first circuit is configured to invert the data inputs if the number of logic high bits in the selected bits is odd and maintain the logic state of the data inputs if the number of logic high bits in the selected bits is even.

8. The random access memory of claim 1, wherein the test circuit comprises:
a mask register configured to store the received mask bits;
a first circuit configured to mask off the two least significant bits of the row address and the two least significant bits of the column address based on the stored mask bits; and
a second circuit configured to exclusive-or the selected bits.

9. A random access memory, comprising:
input pads configured to receive a row address and a column address; and
a test circuit configured to receive the row address and the column address via the input pads and provide test data bits based on the row address and the column address, the test circuit comprising:
a mask register configured to receive mask bits;
a first circuit configured to select bits of the row address and the column address based on the mask bits; and
a second circuit configured to invert data based on the number of the selected bits in one logic state.

10. The random access memory of claim 9, wherein the first circuit masks off bits of the row address and the column address via the mask bits and provides unmasked bits of the row address and the column address in the selected bits.

11. The random access memory of claim 10, wherein the first circuit performs an AND function on the mask bits and at least part of the row address and the column address to provide the unmasked bits of the row address and the column address in the selected bits.

12. The random access memory of claim 10, wherein the second circuit performs an EXCLUSIVE-OR function on the data and the selected bits to invert the data based on the number of the selected bits in one logic state.

13. The random access memory of claim 9, wherein the test circuit comprises:
a data pattern generator that provides data bits and the second circuit performs an EXCLUSIVE-OR function on each of the data bits and the selected bits to provide test data bits.

14. A random access memory, comprising:
means for receiving a row address and a column address;
means for receiving mask bits;
means for selecting bits of the row address and the column address based on the mask bits; and
means for providing at least one test data bit based on the selected bits of the row address and the column address.

15. The random access memory of claim 14, comprising:
means for storing the received mask bits, wherein the means for selecting includes means for masking off bits of the row address and the column address based on the stored mask bits.

16. The random access memory of claim 14, wherein the means for providing the at least one test data bit comprises:
means for inverting data based on the selected bits.

17. The random access memory of claim 14, comprising:
means for inverting data based on the number of the selected bits in one logic state.

18. The random access memory of claim 17, wherein the means for inverting the data comprises:
means for inverting the data if the number of logic high bits in the selected bits is odd; and
means for maintaining the logic state of the data if the number of logic high bits in the selected bits is even.

19. A method for generating test data in an integrated circuit, comprising:
receiving an external row address and an external column address;
receiving mask bits;
selecting bits of the external row address and the external column address based on the mask bits; and
providing at least one test data bit based on the selected bits of the external row address and the external column address.

20. The method of claim 19, comprising:
storing the received mask bits, wherein selecting bits includes masking off bits of the external row address and the external column address based on the stored mask bits.

21. The method of claim 19, wherein providing the at least one test data bit comprises:
inverting data based on the selected bits.

22. The method of claim 19, comprising:
inverting data based on the number of the selected bits in one logic state.

23. The method of claim 22, wherein inverting the data comprises:
inverting the data if the number of logic high bits in the selected bits is odd; and
maintaining the logic state of the data if the number of logic high bits in the selected bits is even.

24. A method for generating test data in a random access memory, comprising:
receiving a row address and a column address via input pads;
receiving mask bits;
selecting bits of the row address and the column address based on the mask bits; inverting data based on the number of the selected bits in one logic state; and
providing test data bits based on the inverted data.

25. The method of claim 24, wherein selecting bits comprises:
masking off bits of the row address and the column address via the mask bits; and
providing unmasked bits of the row address and the column address in the selected bits.

26. The method of claim 25, wherein:
masking off bits includes performing an AND function on the mask bits and at least part of the row address and the column address; and
inverting data includes performing an EXCLUSIVE-OR function on the data and the selected bits.
